(19) United States
(12) Patent Application Publication
(10) Pub. No.: US 2023/0380147 A1
(43) Pub. Date: Nov. 23, 2023

(54) MANUFACTURING METHOD OF SEMICONDUCTOR DEVICE AND SEMICONDUCTOR DEVICE

(71) Applicant: CHANGXIN MEMORY TECHNOLOGIES, INC., Hefei City (CN)

(72) Inventor: Shuai GUO, Hefei City (CN)

(21) Appl. No.: 18/364,489

(22) Filed: Aug. 3, 2023

Related U.S. Application Data
(63) Continuation of application No. PCT/CN2022/136864, filed on Dec. 6, 2022.

(30) Foreign Application Priority Data
Jan. 6, 2022 (CN) 202210010114.9

(51) Int. Cl. H10B 12/00

(52) U.S. Cl. CPC H10B 12/50; H10B 12/0335; H10B 12/315; H10B 12/34

(57) ABSTRACT

Embodiments of the present disclosure provide a manufacturing method of a semiconductor device and a semiconductor device, relating to the technical field of semiconductors. The manufacturing method of a semiconductor device includes: providing a first substrate; forming an array structure layer on the first substrate; forming an insulating material layer on the array structure layer; forming a second substrate on the insulating material layer; and forming a transistor of a peripheral circuit layer on the second substrate.

### CROSS-REFERENCE TO RELATED APPLICATIONS

This is a continuation of International Patent Application No. PCT/CN2022/136864, filed on Dec. 6, 2022, which claims priority to Chinese Patent Application No. 202210010114.9, titled “MANUFACTURING METHOD OF SEMICONDUCTOR DEVICE AND SEMICONDUCTOR DEVICE” and filed on Jan. 6, 2022. The disclosures of International Patent Application No. PCT/CN2022/136864 and Chinese Patent Application No. 202210010114.9 are incorporated herein by reference in their entireties.

### TECHNICAL FIELD

The present disclosure relates to, but is not limited to, a manufacturing method of a semiconductor device and a semiconductor device.

### BACKGROUND

With the development of the semiconductor industry, how to further increase the storage density and reduce the cost is an important research topic for relevant personnel in the field of semiconductors. Currently, the research mainly focuses on how to reduce the size of memory cells, and how to reduce peripheral circuits is rarely studied.

It is currently known that, in conventional semiconductor devices, transistors and memory arrays in a logic circuit are usually arranged in parallel. However, under current technical conditions, the size of the memory cells is almost close to the physical limit that the current technology can achieve, and it is extremely difficult to increase the storage density of the semiconductor devices by reducing the size of the memory cells.

### SUMMARY

An overview of the subject described in detail in the present disclosure is provided below, which is not intended to limit the protection scope of the claims.

The present disclosure provides a manufacturing method of a semiconductor device and a semiconductor device.

According to a first aspect of embodiments of the present disclosure, a manufacturing method of a semiconductor device is provided. The manufacturing method of a semiconductor device includes:
providing a first substrate;
forming an array structure layer on the first substrate;
forming an insulating material layer on the array structure layer;
forming a second substrate on the insulating material layer; and
forming a transistor of a peripheral circuit layer on the second substrate.

According to a second aspect of the embodiments of the present disclosure, a semiconductor device is provided. The semiconductor device includes: a first substrate, an array structure layer, an insulating material layer, a second substrate and a peripheral circuit layer sequentially stacked from bottom to top, where
a memory cell array is arranged in the array structure layer, and a transistor is arranged in the peripheral circuit layer.

Other aspects of the present disclosure are understandable upon reading and understanding of the accompanying drawings and detailed description.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals represent similar elements. The accompanying drawings in the following description illustrate some rather than all of the embodiments of the present disclosure. Those skilled in the art may obtain other accompanying drawings based on these accompanying drawings without creative efforts.

FIG. 1 is a flowchart of a manufacturing method of a semiconductor device according to one embodiment of the present disclosure.

FIG. 2 to FIG. 19a and FIG. 19b are schematic diagrams of various steps in a manufacturing method of a semiconductor device according to one embodiment of the present disclosure.

FIG. 20a and FIG. 20b are schematic structural cross-sectional diagrams of a semiconductor device according to one embodiment of the present disclosure.

### REFERENCE NUMERALS

10—Array structure layer; 110—First substrate; 111—Bit line; 112—Word line; 120—Stacked structure; 121—First sacrificial layer; 122—First support layer; 123—Second sacrificial layer; 124—Second support layer; 125—Capacitor hole; 126—Second conductive material layer; 127—First semiconductor material; 128—Etched hole; 129—Dielectric layer; 1201—Third conductive material layer; 1202—Second semiconductor material; 130—Isolation layer; 131—Capacitor wire hole; 132—Capacitor wire; 133—First conductive material layer; 140—Intermediate structure layer; 20—Insulating material layer; 300—Second substrate; 30—Peripheral circuit layer; 301—Drain/source region; 3011—Channel region; 3012—Isolation trench; 302—Isolation structure; 303—Gate dielectric layer; 304—Conductive material layer; 305—Contact material layer; 306—Mask pattern; 307—First trench; 308—Second trench; and 310—Transistor.

### DETAILED DESCRIPTION

The technical solutions in the embodiments of the present disclosure are described below clearly and completely referring to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

With the development of the semiconductor industry, it is necessary to continuously increase the storage density of the semiconductor device. There are generally two directions to increase the storage density. One is to continuously reduce the line width and reduce the size of the memory cells; and the other is to modify the layout and overlap different functional regions in a vertical direction. Currently known research directions mainly focus on how to reduce the size of the cells, but less research on how to reduce the peripheral circuits. The embodiments of the present disclosure adopt the second idea: arranging a peripheral circuit layer on an array region to implement stacking in the vertical direction, thereby increasing the storage density.

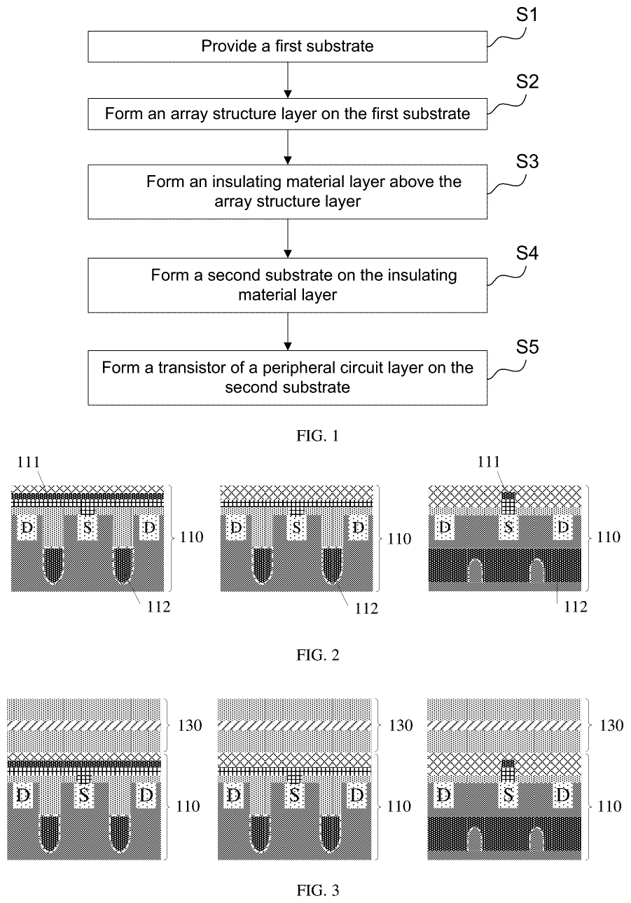

FIG. 1 shows a manufacturing method of a semiconductor device according to one embodiment of the present disclosure. The manufacturing method of a semiconductor device includes the following steps:

Step S1: provide a first substrate. The first substrate is a conventional semiconductor structure configured to form a memory cell array structure.

Step S2: form an array structure layer on the first substrate. In the present disclosure, the formation of the array structure layer of memory cells may be the formation process of a memory cell array composed of memory transistors and capacitors (1T1C) in a dynamic random access memory (DRAM) array.

Step S3: form an insulating material layer on the array structure layer. To arrange the peripheral circuit layer on the array region, it is necessary to set a layer of insulating material on the array region to isolate the peripheral circuit layer and the array region, thereby avoiding electron migration between the peripheral circuit layer and the array region, and ensuring that the peripheral circuit layer and the array region do not affect each other and both can work normally.

Step S4: form a second substrate on the insulating material layer. After the second substrate is formed, the drain/source region is formed by implanting ions, and the drain/source region is configured to form a source and a drain of a final transistor. It is also necessary to form several isolation structures at intervals between different drain/source regions to isolate different transistors.

Step S5: form a transistor of the peripheral circuit layer on the second substrate. A contact material layer and a conductive material layer connected to the drain/source region are formed on the second substrate to form a transistor structure of a final peripheral circuit, and it may be, for example, a complementary metal oxide semiconductor (CMOS) structure.

The manufacturing method of a semiconductor device provided in the embodiments of the present disclosure adopts an up-down arrangement mode, in which the memory array is at the bottom and the transistor of a logic circuit is at the top, thereby reducing the area of the semiconductor device occupied by the peripheral circuit layer, allowing the semiconductor device having the same area to accommodate more memory cells, and increasing the storage density of the semiconductor device.

FIG. 2 to FIG. 19a and FIG. 19b are schematic structural diagrams of various steps in a manufacturing method of a semiconductor device according to one embodiment of the present disclosure. The manufacturing method of a semiconductor device provided in the embodiments of the present disclosure is further described below in detail with reference to FIG. 19a and FIG. 19b. In FIG. 2 to FIG. 19a and FIG. 19b, the left side of each figure is an X-axis, namely, the cross-sectional view along the extension direction of a vertical word line (WL); the middle is the cross-sectional view of an X-axis projection plane; and the right side is a Y-axis, namely, the cross-sectional view along the extension direction of a vertical bit line (BL).

First perform step S1: provide a first substrate.

Next, perform step S2: form an array structure layer on the first substrate. A memory array structure mainly includes WL, BL, and a capacitor structure.

As shown in FIG. 2, the BL 111 and the WL 112 are first formed in the first substrate 110, and are perpendicular to each other. The BL 111 and the WL 112 are both made of a conductive material, which may be a metal or a metal compound, and may be, for example, one or a combination of more of tungsten (W)/tungsten nitride (WN)/tungsten silicide (WSi)/titanium nitride (TiN).

In the embodiments of the present disclosure, after the WL and the BL are formed, the capacitor structure is continuously formed on the WL and the BL.

As shown in FIG. 3, before the capacitor structure is formed, the isolation layer 130 needs to be formed on the first substrate 110. The isolation layer 130 may be made of a semiconductor insulating material, which may be, for example, an Si₃N₄ material. The isolation layer 130 may also be designed as a multi-layer structure, which may be, for example, a three-layer stacked structure, and a first layer and a third layer are both made of the Si₃N₄ material.

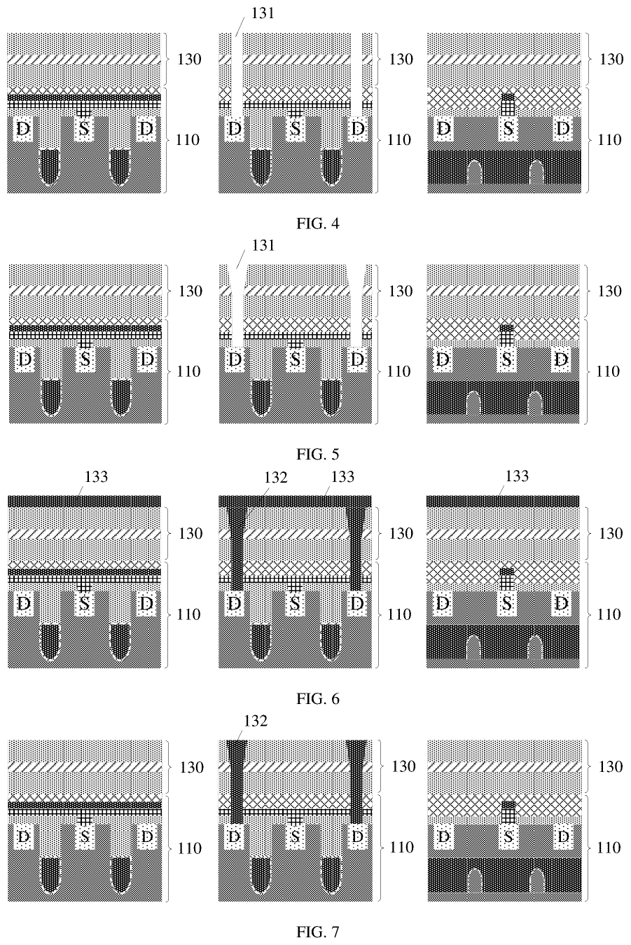

After the isolation layer 130 is formed, a process of connecting an external capacitor wire is performed, and the specific process refers to FIG. 4 to FIG. 7. As shown in FIG. 4, a capacitor wire hole 131 is etched in the isolation layer 130. As shown in FIG. 5, the top of the capacitor wire hole 131 is amplified. As shown in FIG. 6, a conductive material is deposited in the amplified capacitor wire hole 131 to form a capacitor wire 132, and a first conductive material layer 133 covers the upper surface of the isolation layer 130. As shown in FIG. 7, the surface of the conductive material on the isolation layer 130 is planarized, and the first conductive material layer 133 is removed, such that the top end of the capacitor wire 132 is flush with the top end of the isolation layer 130. In some embodiments, the material of the capacitor wire 132 may be metal tungsten (W).

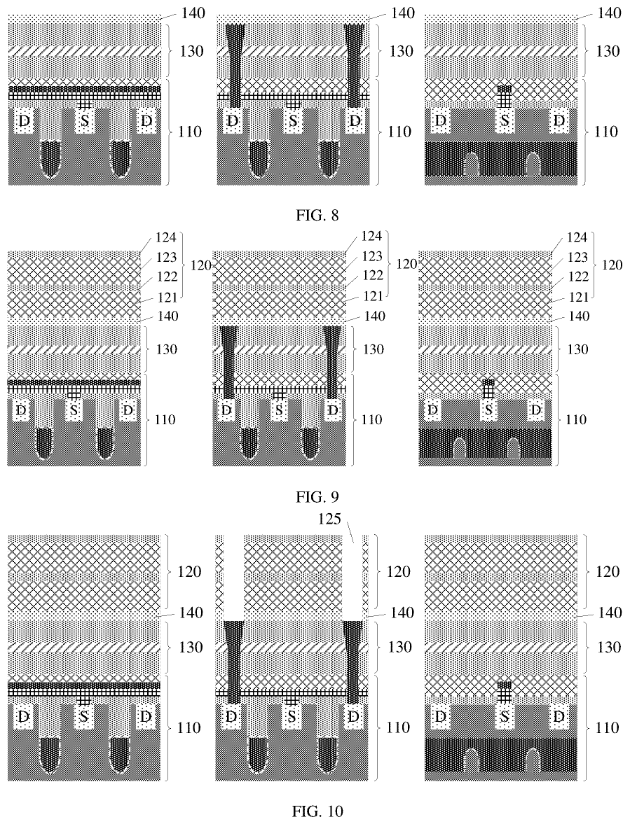

After that, the capacitor structure is manufactured, and the specific process refers to FIG. 8 to FIG. 16.

As shown in FIG. 8, an intermediate structure layer 140 is formed on the isolation layer 130. In some embodiments, the intermediate structure layer 140 may be formed by depositing a semiconductor material, which may be, for example, a silicon-boron compound (SiBN).

As shown in FIG. 9, a stacked structure 120 is formed on the intermediate structure layer 140. The stacked structure 120 includes a first sacrificial layer 121, a first support layer 122, a second sacrificial layer 123 and a second support layer 124, which are sequentially deposited from bottom to top. In some embodiments, the materials of the first sacrificial layer 121 and the second sacrificial layer 123 may be silicon dioxide (SiO₂) or a boron-phosphosilicate glass (BPSG) material, and the first support layer 122 and the second support layer 124 may be made of an Si₃N₄ material.

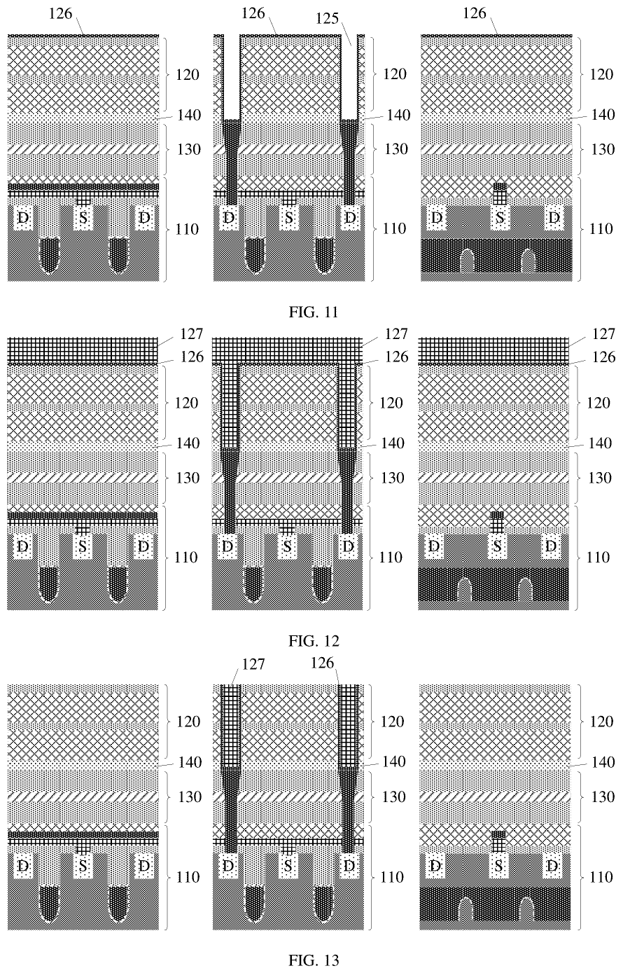

As shown in FIG. 10, a capacitor hole 125 is etched in the stacked structure 120. As shown in FIG. 11, a second conductive material layer 126 is separately deposited on the upper surface of the stacked structure 120 and a side wall and a bottom of the capacitor hole 125 as a bottom electrode of the capacitor. In some embodiments, the second conductive material layer 126 may be made of a metal material, such as metal tungsten (W) and titanium nitride (TiN).

As shown in FIG. 12, a first semiconductor material 127 is deposited on the second conductive material layer 126 in the capacitor hole 125, and the first semiconductor material 127 is filled in the capacitor hole 125 and covers the second conductive material layer 126 on the upper surface of the stacked structure 120. As shown in FIG. 13, a first semiconductor material 127 and part of the second conductive material layer 126 are etched back, the second conductive material layer 126 and the first semiconductor material 127 on the upper surface of the stacked structure 120 are removed, and only the second conductive material layer 126 and the first semiconductor material 127 in the capacitor hole 125 are retained. Planarization is performed to make the second conductive material layer 126 and the first semiconductor material 127 in the capacitor hole 125 flush with the upper surface of the stacked structure 120. In some embodiments, the first semiconductor material 127 may be amorphous silicon (α-Si).

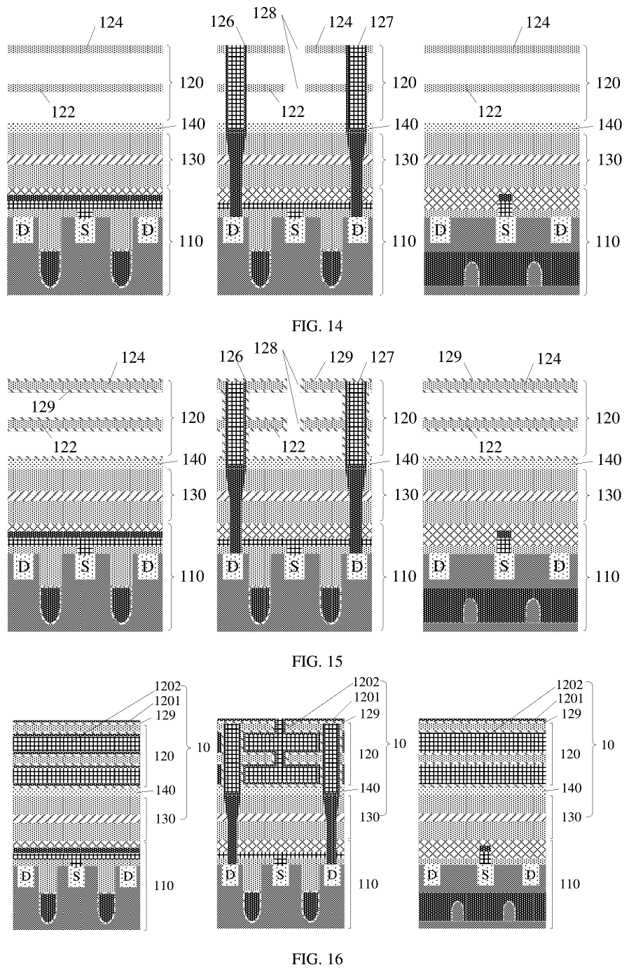

As shown in FIG. 14, etched holes 128 are formed in the first support layer 122 and the second support layer 124, and the first sacrificial layer 121 and the second sacrificial layer 123 are removed through the etched holes 128. At this time, the first support layer 122, the second support layer 124, the second conductive material layer 126 in the capacitor hole 125, and the first semiconductor material 127 in the capacitor hole 125 are only retained in the stacked structure 120.

As shown in FIG. 15, a dielectric layer 129 separately covers the upper surface of the intermediate structure layer 140, the upper surface and the lower surface of the first support layer 122, the upper surface and the lower surface of the second support layer 124, and the outer side periphery of the second conductive material layer 126 in the capacitor hole. In some embodiments, the dielectric layer 129 may be a material layer with a high dielectric constant.

As shown in FIG. 16, a third conductive material layer 1201 is formed on the surface of the dielectric layer 129 as a top electrode, and a second conductive material 1202 is filled in the remaining space of the stacked structure 120. The second conductive material 1202 may be a silicon germanide (SiGe) material. So far, the formation of the capacitor structure and the array structure layer 10 are completed.

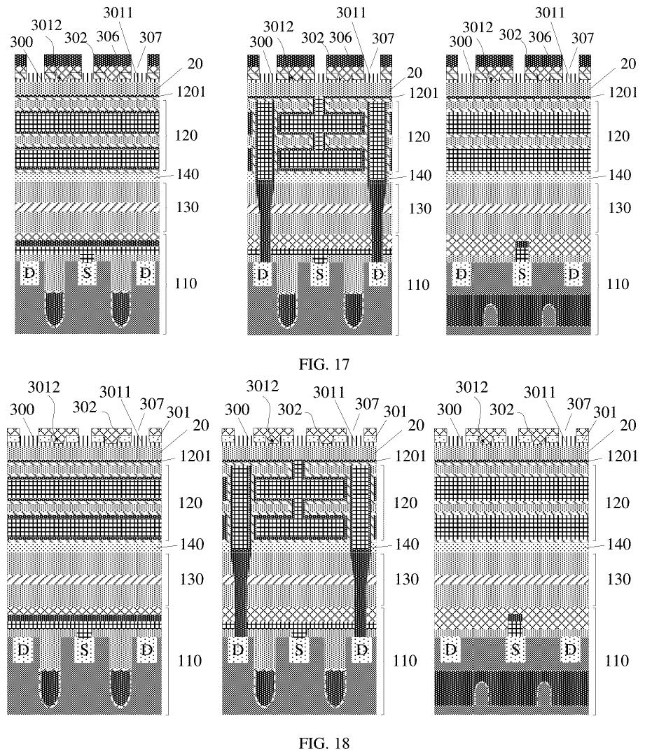

Next, as shown in FIG. 17, perform step S3: form an insulating material layer 20 on the array structure layer 10.

In some embodiments, the insulating material layer 20 may be made of an Si₃N₄ material.

Next, as shown in FIG. 17, perform step S4: form a second substrate 300 on the insulating material layer 20.

In some embodiments, the second substrate 300 may be made of a molybdenum disulfide (MoS₂) material.

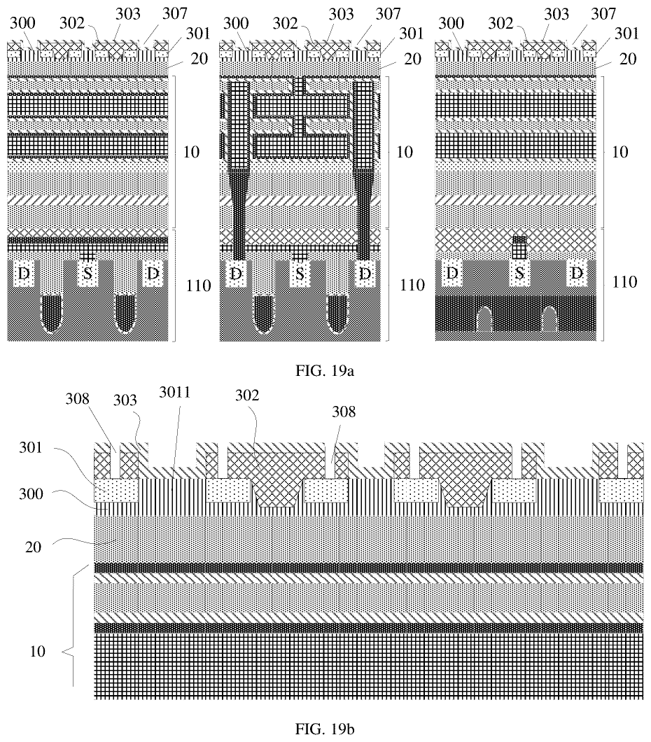

In some embodiments, as shown in FIG. 18, the manufacturing method of a semiconductor device further includes the following steps after step S4:
Step S41: implant ions in the second substrate 300 to form a drain/source region 301.

In some embodiments, as shown in FIG. 17 and FIG. 18, step S41 may include the following steps:
Step S411: form a sacrificial layer (not shown in the figures) on the second substrate 300, where the sacrificial layer may be a thin silicon dioxide layer to protect the second substrate 300 during ion implantation.
Step S412: implant first doped ions in the second substrate 300 to form a channel region 3011, where the first doped ions may be P-type doped ions.
Step S413: form a mask pattern layer (not shown in the figures) on the sacrificial layer.
Step S414: implant second doped ions in the second substrate 300 through the sacrificial layer exposed by the mask pattern layer to form the drain/source region 301, where the second doped ions may be N-type doped ions
Step S415: remove the sacrificial layer and the mask pattern layer.
Step S42: partially etch the second substrate 300 to form an isolation trench 3012.
Step S43: form an isolation structure 302 that is filled in the isolation trench 3012, covers the upper surface of the second substrate 300, and is configured to separate two adjacent transistors.
Step S44: form, in the isolation structure 302, a first trench 307 exposing the second substrate 300.

In the embodiments of the present disclosure, the mask pattern 306 needs to be first formed on the upper surface of the isolation structure 302 to expose part of the isolation structure 302; the isolation structure 302 is then etched based on the mask pattern 306 to form the first trench 307, and the mask pattern is shown in FIG. 17; and finally, the mask pattern 306 is removed, and the formed semiconductor device structure is shown in FIG. 18.

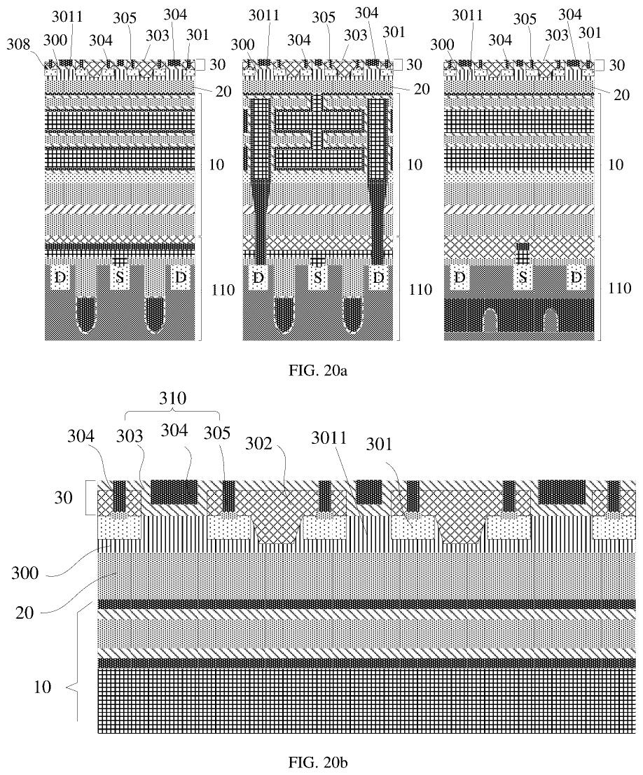

After that, perform step S5: as shown in FIG. 19a to FIG. 20b, form a transistor 310 of the peripheral circuit layer 30 on the second substrate 300.

In some embodiments, step S5 includes the following steps:

Step S51: as shown in FIG. 19a and FIG. 19b, form a gate dielectric layer 303 covering a surface of the isolation structure 302 and a surface of the first trench 307.

Step S52: partially etch the gate dielectric layer 303 and the isolation structure 302 to form a second trench 308 exposing the drain/source region 301.

Step S53: as shown in FIG. 20a and FIG. 20b, form a contact material layer 305, where the contact material layer 305 covers a bottom surface of the second trench 308.

In some embodiments, the material of the contact material layer 305 is metal bismuth (Bi). The material MoS₂ of the second substrate 300 and the metal bismuth (Bi) are in good ohmic contact, thereby further improving the performance of the device.

In some embodiments, after forming the contact material layer 305 in step S53, the manufacturing method of a semiconductor device further includes:
form a barrier layer (not shown in the figures), where the barrier layer covers the contact material layer 305 and side walls of the second trench 308.

Step S54: form a conductive material layer 304, where the conductive material layer 304 is filled in the second trench 308 and the first trench 307.

In some embodiments, step S54 of forming the conductive material layer 304 includes:
Step S541: form the conductive material layer 304, where the conductive material layer 304 is filled in the second trench 308 and the first trench 307, and covers an upper surface of the gate dielectric layer 303.

Step S542: etch back the conductive material layer 304 on the upper surface of the gate dielectric layer 303.

In some embodiments, as shown in FIG. 19b, the lower surface of the second trench 308 is flush with the upper surface of the second substrate 300.

In some other embodiments, as shown in FIG. 20a, the lower surface of the second trench 308 is lower than the upper surface of the second substrate 300. In these embodiments, the second trench 308 located in the second substrate 300 is wider than the second trench 308 located in the isolation structure 302. That is to say, the second trench 308 is in a shape of a narrow top and a wide bottom, such that the formed contact material layer 305 located in the second substrate 300 is wider than the conductive material layer 304 located in the isolation structure 302. In this way, the contact area between the contact material layer 305 and the drain/source region 301 can be increased, and the performance of the semiconductor device is further improved.

The isolation structure 302, the gate dielectric layer 303, the contact material layer 305 and the conductive material layer 304 that are located on the second substrate 300 form the peripheral circuit layer 30, where the gate dielectric layer 303, the contact material layer 305 and the conductive material layer 304 are bonded to each other to form the transistor 310 of the peripheral circuit layer 30.

The manufacturing method of a semiconductor device provided in the embodiments of the present disclosure adopts an up-down arrangement mode, in which the memory array is at the bottom and the transistor of the logic circuit is at the top, thereby reducing the area of the semiconductor device occupied by a peripheral circuit, allowing the semiconductor device having the same area to accommodate more memory cells, and increasing the storage density of the semiconductor device.

In addition, the embodiments of the present disclosure further provide a semiconductor device, which is manufactured by the manufacturing method of a semiconductor device provided in the above embodiments. FIG. 20a and FIG. 20b are schematic structural cross-sectional diagrams of a semiconductor device according to one embodiment of the present disclosure. As shown in FIG. 20a and FIG. 20b, the semiconductor device includes: a first substrate 110, an array structure layer 10, an insulating material layer 20, a second substrate 300 and a peripheral circuit layer 30 sequentially stacked from bottom to top, where a memory cell array is arranged in the array structure layer 10, and a transistor 310 is arranged in the peripheral circuit layer 30.

The solution of the present disclosure adopts an up-down arrangement mode, in which the memory array is at the bottom and the transistor of the logic circuit is at the top, thereby reducing the area of the semiconductor device occupied by a peripheral circuit, allowing the semiconductor device having the same area to accommodate more memory cells, and increasing the storage density of the semiconductor device.

In some embodiments, as shown in FIG. 17, FIG. 18 and FIG. 19b, a plurality of isolation trenches 3012 are arranged at intervals on an upper surface of the second substrate 300, and drain/source regions 301 are arranged on two sides of each of the isolation trenches 3012; the second substrate 300 further includes a plurality of isolation structures 302, and each of the isolation structures 302 is filled in one of the isolation trenches 3012 and partially covers upper surfaces of the drain/source regions 301 on two sides of the isolation trench 3012; a first trench 307 is formed in a surface of the second substrate 300 between two adjacent ones of the isolation structures 302; and a second trench 308 passing through the isolation structure 302 is arranged on each of the drain/source regions 301.

The isolation structure 302 is configured to separate two adjacent transistors 310, thereby avoiding mutual interference between adjacent transistors 310, and improving the performance of the semiconductor device.

In some embodiments, as shown in FIG. 20a and FIG. 20b, the peripheral circuit layer 30 includes a gate dielectric layer 303, a contact material layer 305, and a conductive material layer 304, where the gate dielectric layer 303 covers an upper surface of the isolation structure 302 and an upper surface of the first trench 307, the contact material layer 305 covers a bottom surface of the second trench 308, and the conductive material layer 304 is filled in a remaining part of the second trench 308 and the first trench 307. The gate dielectric layer 303, the contact material layer 305 and the conductive material layer 304 are bonded to each other to form the transistor 310 of the peripheral circuit layer 30.

In some embodiments, a channel region 3011 is formed in the second substrate 300 by implanting first doped ions, and the drain/source region 301 is formed by implanting second doped ions. The first doped ions are P-type doped ions, and the second doped ions are N-type doped ions.

In some embodiments, the peripheral circuit layer 30 further includes a barrier layer (not shown in the figures), where the barrier layer covers the contact material layer 305 and side walls of the second trench 308. The barrier layer is sandwiched between the contact material layer 305 and the conductive material layer 304 and between the conductive material layer 304 and side walls of the second trench 308, thereby preventing the conductive material layer 304 from being in direct contact with the contact material layer 305 and the isolation structure 302.

In some embodiments, the lower surface of the second trench 308 is flush with the upper surface of the second substrate 300. It is necessary to ensure that the contact material layer 305 is in contact with the second substrate 300, thereby preventing the contact material layer 305 from being separated from the second substrate 300 by the isolation structure 302.

In some embodiments, the lower surface of the second trench 308 is lower than the upper surface of the second substrate 300. The second trench 308 located in the second substrate 300 is wider than the second trench 308 located in the isolation structure 302. That is to say, the second trench 308 is in a shape of a narrow top and a wide bottom, such that the formed contact material layer 305 located in the second substrate 300 is wider than the conductive material layer 304 located in the isolation structure 302. In this way, the contact area between the contact material layer 305 and the second substrate 300 can be increased, and the performance of the semiconductor device is improved.

In some embodiments, the material of the contact material layer 305 is bismuth, and the material of the second substrate 300 is molybdenum disulfide.

The manufacturing method of a semiconductor device in the embodiments of the present disclosure is similar to that in the above embodiments. For the technical features not disclosed in detail in the embodiments of the present disclosure, please refer to the above embodiments for understanding, and details are not repeated herein.

The solution of the present disclosure redesigns the DRAM layout, designs the transistor of the logic circuit at the upper part of the memory array, and solves the substrate problem by MoS₂. At the same time, because MoS₂ and the semi-metal bismuth (Bi) are in good ohmic contact, the performance of the device can be further improved. Those skilled in the art can understand that this solution may also be applied to other semiconductor devices, and may be applied to memory devices such as a static random-access memory (SRAM), a flash memory (flash EPROM), a ferroelectric random-access memory (FeRAM), a magnetic random access memory (MRAM), and a phase change random-access memory (PRAM).

In the conventional solutions, the transistor of the peripheral logic circuit and the memory array are arranged in parallel, the area of the memory cell on the semiconductor device accounts for 50% to 55%, the core region accounts for 25% to 30%, and the peripheral circuit accounts for about 20%. After the solution of the present disclosure adopts the up-down arrangement mode, the area occupied by the peripheral circuit part can be saved, more memory cells are accommodated on the semiconductor device, and the storage density of the semiconductor device is increased.

The embodiments or implementations of this specification are described in a progressive manner, and each embodiment focuses on differences from other embodiments. The same or similar parts between the embodiments may refer to each other.

In the description of this specification, the description referring to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail referring to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the manufacturing method of a semiconductor device and the semiconductor device provided by the present disclosure, the up-down arrangement mode, in which the memory array is at the bottom and the transistor of the logic circuit is at the top is adopted, thereby reducing the area of the semiconductor device occupied by the peripheral circuit, allowing the semiconductor device having the same area to accommodate more memory cells, and increasing the storage density of the semiconductor device.

1. A manufacturing method of a semiconductor device, comprising:
providing a first substrate;
forming an array structure layer on the first substrate;
forming an insulating material layer on the array structure layer;
forming a second substrate on the insulating material layer; and
forming a transistor of a peripheral circuit layer on the second substrate.

2. The manufacturing method of a semiconductor device according to claim 1, after forming the second substrate on the insulating material layer, further comprising:
implanting ions in the second substrate to form a drain/source region;
partially etching the second substrate to form an isolation trench;
forming an isolation structure that is filled in the isolation trench and covers an upper surface of the second substrate; and
forming, in the isolation structure, a first trench exposing the second substrate.

3. The manufacturing method of a semiconductor device according to claim 2, wherein the forming a transistor of a peripheral circuit layer on the second substrate comprises:
forming a gate dielectric layer covering a surface of the isolation structure and a surface of the first trench;
partially etching the gate dielectric layer and the isolation structure, to form a second trench exposing the drain/source region;
forming a contact material layer, wherein the contact material layer covers a bottom surface of the second trench; and
forming a conductive material layer, wherein the conductive material layer is filled in the second trench and the first trench.

4. The manufacturing method of a semiconductor device according to claim 3, wherein the forming a conductive material layer comprises:
forming the conductive material layer, wherein the conductive material layer is filled in the second trench and the first trench, and covers an upper surface of the gate dielectric layer; and
etching back the conductive material layer on the upper surface of the gate dielectric layer.

5. The manufacturing method of a semiconductor device according to claim 2, wherein the implanting ions in the second substrate to form a drain/source region comprises:
forming a sacrificial layer on the second substrate;
implanting first doped ions in the second substrate to form a channel region;
forming a mask pattern layer on the sacrificial layer;
implanting second doped ions in the second substrate through the sacrificial layer exposed by the mask pattern layer, to form the drain/source region; and
removing the sacrificial layer and the mask pattern layer.

6. The manufacturing method of a semiconductor device according to claim 3, after forming the contact material layer, further comprising:
forming a barrier layer, wherein the barrier layer covers the contact material layer and side walls of the second trench.

7. The manufacturing method of a semiconductor device according to claim 3, wherein a lower surface of the second trench is flush with the upper surface of the second substrate.

8. The manufacturing method of a semiconductor device according to claim 3, wherein a lower surface of the second trench is lower than the upper surface of the second substrate.

9. The manufacturing method of a semiconductor device according to claim 7, wherein the second trench located in the second substrate is wider than the second trench located in the isolation structure.

10. The manufacturing method of a semiconductor device according to claim 3, wherein a material of the contact material layer is bismuth, and a material of the second substrate is molybdenum disulfide.

11. A semiconductor device, comprising: a first substrate, an array structure layer, an insulating material layer, a second substrate and a peripheral circuit layer sequentially stacked from bottom to top, wherein
a memory cell array is arranged in the array structure layer, and a transistor is arranged in the peripheral circuit layer.

12. The semiconductor device according to claim 11, wherein a plurality of isolation trenches are arranged at intervals on an upper surface of the second substrate, and drain/source regions are arranged on two sides of each of the isolation trenches; the second substrate further comprises a plurality of isolation structures, and each of the isolation structures is filled in one of the isolation trenches and partially covers upper surfaces of the drain/source regions on two sides of the isolation trench; a first trench is formed in a surface of the second substrate between two adjacent isolation structures; and a second trench passing through the isolation structure is arranged on each of the drain/source regions.

13. The semiconductor device according to claim 12, wherein the peripheral circuit layer comprises a gate dielectric layer, a contact material layer, and a conductive material layer, wherein the gate dielectric layer covers an upper surface of the isolation structure and an upper surface of the first trench, the contact material layer covers a bottom surface of the second trench, and the conductive material layer is filled in a remaining part of the second trench and the first trench.

14. The semiconductor device according to claim 12, wherein a channel region is formed in the second substrate by implanting first doped ions, and the drain/source region is formed by implanting second doped ions.

15. The semiconductor device according to claim 13, wherein the peripheral circuit layer further comprises a barrier layer covering the contact material layer and side walls of the second trench.

16. The semiconductor device according to claim 13, wherein a lower surface of the second trench is flush with the upper surface of the second substrate.

17. The semiconductor device according to claim 13, wherein a lower surface of the second trench is lower than the upper surface of the second substrate.

18. The semiconductor device according to claim 17, wherein the second trench located in the second substrate is wider than the second trench located in the isolation structure.

19. The semiconductor device according to claim 13, wherein a material of the contact material layer is bismuth, and a material of the second substrate is molybdenum disulfide.
